(19) United States
(12) Patent Application Publication
(10) Pub. No.: US 2009/0219050 A1
(43) Pub. Date: Sep. 3, 2009

(54) METHOD FOR DETECTING A MALFUNCTION IN AN ELECTROMAGNETIC RETARDER

(76) Inventors: Bruno Dessirier, Saint Germain en Laye (FR); Jean-Claude Matt, Dijon (FR); Serge Newiadomy, Clichy Sous Bois (FR)

Correspondence Address: BERENATO, WHITE & STAVISH, LLC, 6550 ROCK SPRING DRIVE, SUITE 240, BETHESDA, MD, 20817, US

(21) Appl. No.: 12/092,139

(22) PCT Filed: Dec. 15, 2006
(86) PCT No.: PCT/FR2006/002750

§ 371 Date: Jul. 7, 2008

(30) Foreign Application Priority Data
Dec. 19, 2005 (FR) 0553939

(51) Int. Cl. G01R 31/34; F16F 15/03

(52) U.S. Cl. 324/772; 188/267

(57) ABSTRACT

A method for detecting a malfunction in an electromagnetic retarder. More specifically, the method relates to a retarder comprising: stator primary coils (8); a control unit (19) for injecting a current into the primary coils (8), the current having an intensity corresponding to an intensity set value (Ci); a sensor (21) which delivers a signal that is representative of an effective intensity value (Ie) of the current passing through the primary coils (8); and a shaft (7) bearing secondary windings (5) defining several phases and field coils (13), as well as a current rectifier (5) which is disposed between the secondary windings (5A, 5B, 5C) and the field coils (13). The method consists in comparing the intensity set value (Ci) and the effective intensity (Ie) in the control unit (19) in order to identify a fault in the event that the intensity set value (Ci) and the effective intensity (Ie) differ by an amount greater than a threshold value. The method is suitable for electric retarders (1) which are intended for heavy vehicles, such as trucks or other vehicles.

### FIELD OF THE INVENTION

The invention concerns a method of detecting a fault in an electrical component carried by a rotary shaft of an electromagnetic retarder. The invention also concerns such an electromagnetic retarder.

The invention applies to a retarder capable of generating a retarding resisting torque on a main or secondary transmission shaft of a vehicle that it equips, when this retarder is actuated.

### PRIOR ART

Such an electromagnetic retarder comprises a rotary shaft that is coupled to the main or secondary transmission shaft of the vehicle in order to exert on it the retarding resisting torque in particular for assisting the braking of the vehicle.

The retarding is generated with field coils supplied with DC current in order to produce a magnetic field in a metal piece made from ferromagnetic material, in order to make eddy currents appear in this metal piece.

The field coils can be fixed so as to cooperate with at least one metal piece made from movable ferromagnetic material having the general appearance of a disc rigidly secured to the rotary shaft.

In this case, these field coils are generally oriented parallel to the rotation axis and disposed around this axis, facing the disc, while being secured to a fixed plate. Two successive field coils are supplied electrically in order to generate magnetic fields in opposite directions.

When these field coils are supplied electrically, the eddy currents that they generate in the disc through their effects oppose the cause that gave rise to them, which produces a resisting torque on the disc and therefore on the rotary shaft, in order to slow down the vehicle.

In this embodiment, the field coils are supplied electrically by a current coming from the electrical system of the vehicle, that is to say for example from a battery of the vehicle. However, in order to increase the performance of the retarder, recourse is had to a design in which a current generator is integrated in the retarder.

Thus, according to another design known from the patent documents EP0331559 and FR1467310, the electrical supply to the field coils is provided by a current generator comprising primary stator coils supplied by the vehicle system, and secondary rotor coils fixed to the rotating shaft, and defining three electrical phases. The field coils are fixed to the rotating shaft while being radially projecting, in order to generate a magnetic field in a fixed cylindrical jacket that surrounds them.

A rectifier such as a diode bridge rectifier is interposed between the secondary rotor windings and the field coils, while also being carried by the rotary shaft. This rectifier converts the three-phase alternating current delivered by the secondary windings of the generator into a direct current supplying the field coils.

Two radially acting field coils consecutive around the rotation axis generate magnetic fields in opposite directions, one generating a field oriented centrifugally, the other a field oriented centripetally.

In operation, the electrical supply to the primary coils enables the generator to produce the supply current to the field coils, which gives rise to eddy currents in the fixed cylindrical jacket so as to generate a resisting torque on the rotary shaft, which slows the vehicle.

In order to reduce the weight and increase further the performance of such a retarder, it is advantageous to couple it to the transmission shaft of the vehicle by means of a speed multiplier, in accordance with the solution adopted in the patent document EP1527509.

The rotation speed of the retarder shaft is then multiplied compared with the rotation speed of the transmission shaft to which it is coupled. This arrangement significantly increases the electrical power delivered by the generator and therefore the power of the retarder.

In the event of malfunctioning of the current rectifier, the electric power transmitted to the field coils decreases, which results in a reduction in the retarding torque that can be exerted by the retarder.

Such a malfunctioning of the retarder may be partial, that is to say concern only one of the electrical phases of the current delivered by the secondary windings, which is then not converted by the rectifier.

The generator being for example of the three-phase type, in this case the retarding torque available drops by approximately one third of its nominal value, so that the driver of the vehicle is not necessarily aware of this drop, all the more so since such a retarder is generally used to supplement a traditional braking system, which makes the difference even less perceptible.

Such a retarder may also be controlled by means of a central processing unit that, from braking commands exerted by the driver, distributes the power demanded of the traditional brakes and that demanded of the retarder. In this case, the driver may not directly note a drop in the retarding torque supplied by the retarder.

In addition, the detection of a malfunctioning of the bridge rectifier or another electrical component carried by the rotary shaft by means of electrical sensors or the like mounted on the rotary shaft requires transmitting data from the rotary shaft to fixed parts of the retarder, which leads to complex solutions.

### OBJECT OF THE INVENTION

The aim of the invention is to propose a solution for detecting at lower cost a malfunctioning of an electrical component carried by the rotary shaft.

To this end, the object of the invention is a method of detecting a fault in an electrical component carried by a rotary shaft of an electromagnetic retarder, this retarder comprising primary stator coils, a control box for injecting into these coils a current having an intensity corresponding to a theoretical intensity dependent on a set intensity value, a sensor delivering a signal representing an actual intensity value of the current flowing in these primary coils, a rotary shaft carrying secondary windings defining several phases and field coils as well as a current rectifier interposed between the secondary windings and the field coils, this method consisting of comparing, in the control box, the theoretical intensity and the actual intensity so as to identify a fault in the event of a difference between the theoretical intensity and the actual intensity greater than a threshold value.

The invention thus makes it possible to identify the presence of an electrical problem at the electrical component carried by the rotary shaft simply by analysis of the electrical behaviour of the primary coils when they are excited. It is thus not necessary to provide a device for the transmission of data between the rotary shaft and a fixed part of the retarder, which makes it possible to use a fault detector having a very simple design.

The invention also concerns a method as defined above, consisting of determining a difference between the theoretical intensity and a minimum or maximum value taken by the actual intensity of the current actually passing through the primary coils over a predetermined interval of time.

The invention also concerns a method as defined above in which the theoretical intensity is determined in the control box from the set intensity value and data representing a transfer function of the retarder.

The invention also concerns a method as defined above, consisting of taking into account the set intensity value as the value representing the theoretical intensity.

The invention also concerns a method as defined above, consisting of slaving, from the control box, the current injected into the primary coils to the signal delivered by the current sensor, and providing primary coils having a time constant three times greater than the time constant of the secondary coils.

The invention also concerns a method as defined above, consisting of slaving, from the control box, the current injected into the primary coils to the signal delivered by the sensor, with a slaving having a reaction time sufficiently long to be insensitive to a fault in an electrical component carried by the rotary shaft.

The invention also concerns a method as defined above, consisting of providing a slaving having a cutoff frequency Fc satisfying the relationship Fc<1/3.2.pi.T2, in which Fc is expressed in hertz and in which T2 is the time constant of the secondary winding expressed in seconds.

The invention also concerns a method as defined above, consisting of using inductive measuring turns as an actual current sensor.

The invention also concerns an electromagnetic retarder comprising primary stator coils, a control box for injecting into these primary coils a current having an intensity corresponding to a theoretical intensity dependent on a set intensity value, a sensor delivering a signal representing an actual intensity value of the current flowing in these primary coils, a rotary shaft carrying secondary windings defining several phases and field coils as well as a current rectifier interposed between the secondary windings and the field coils, and means of comparing the theoretical intensity with the actual intensity in order to identify an operating fault in an electrical component carried by the rotary shaft in the event of a difference between the theoretical intensity and the actual intensity greater than a threshold value.

The invention also concerns an electromagnetic retarder as defined above, comprising means of slaving the current injected into the primary coils to the signal delivered by the sensor, and primary coils having a time constant greater that three times the time constant of the secondary windings.

The invention also concerns an electromagnetic retarder as defined above, comprising means of slaving the current injected into the primary coils to the signal delivered by the sensor, in which this slaving has a cutoff frequency Fc satisfying the relationship Fc<1/3.2.pi.T2, in which Fc is expressed in hertz and in which T2 is the time constant of the secondary windings expressed in seconds.

The invention also concerns an electromagnetic retarder as defined above in which the sensor comprises one or more measuring field turns wound with the primary coils.

### BRIEF DESCRIPTION OF THE DRAWINGS

The invention will now be described in more detail and with reference to the accompanying drawings, which illustrate an embodiment thereof by way of non-limitative example.

FIG. 1 is an overall view with local cutaway of an electromagnetic retarder to which the invention applies;

FIG. 2 is a schematic representation of the electrical components of the retarder according to the invention;

FIG. 3 is a graph as a function of time of the actual current flowing in the primary coils of the retarder having an operating fault in its rectifier;

FIG. 4 is a schematic representation of a slaving of the current of an electromagnetic retarder.

### DESCRIPTION OF EMBODIMENTS OF THE INVENTION

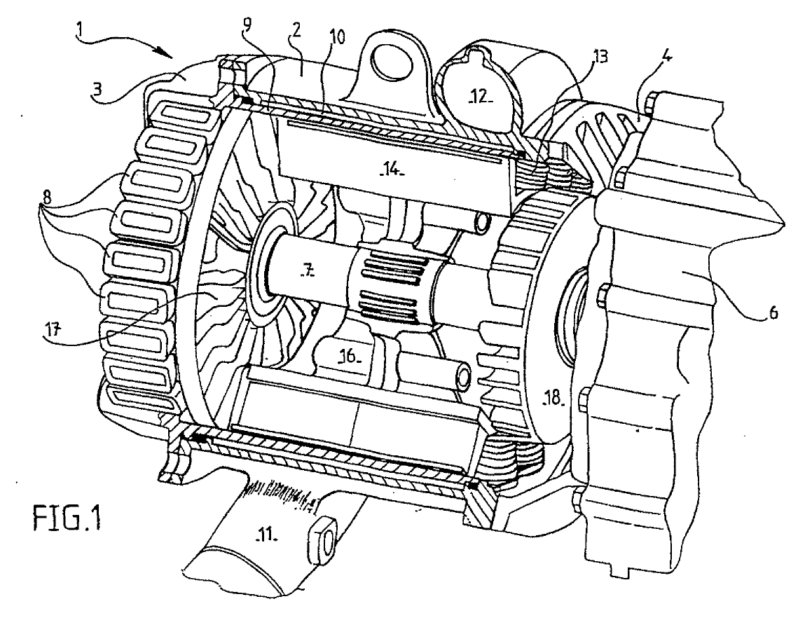

In FIG. 1, the electromagnetic retarder 1 comprises a main casing 2 with a cylindrical shape overall having a first end closed by a cover 3 and a second end closed by a coupling piece 4 by means of which this retarder 1 is fixed to a gearbox casing either directly or indirectly, here via a speed multiplier referenced 6.

This casing 2, which is fixed, encloses a rotary shaft 7 that is coupled to a transmission shaft, not visible in the figure, such as a main transmission shaft to the vehicle wheels, or secondary such as a secondary gearbox output shaft via the speed multiplier 6. In a region corresponding to the inside of the cover 3 a current generator is situated, which comprises fixed or stator primary coils 8 that surround rotor secondary windings, secured to the rotary shaft 7.

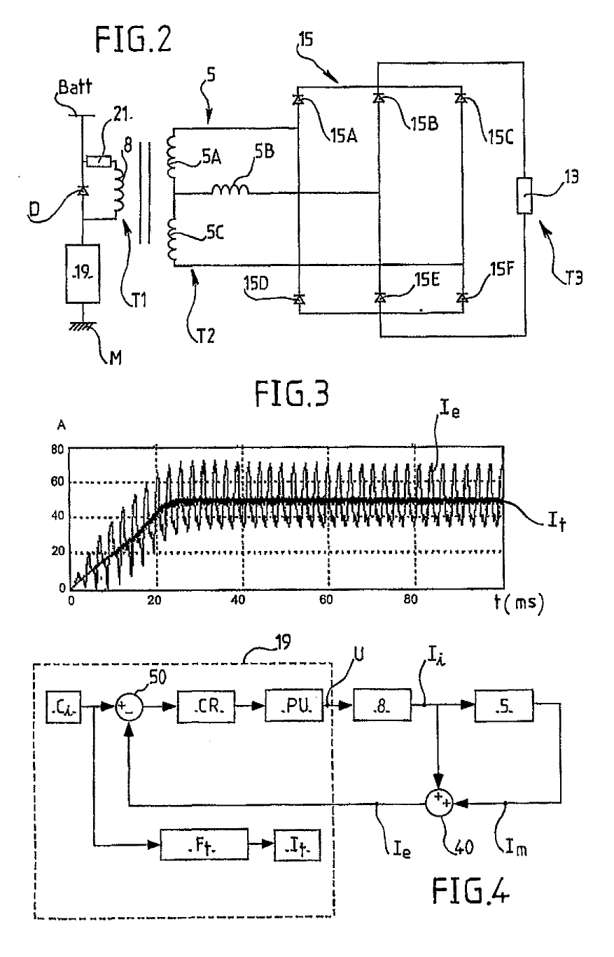

These secondary windings are shown symbolically in FIG. 2, being marked by the reference 5. These secondary windings 5 comprise here three distinct windings 5a, 5b and 5c for delivering a three-phase alternating current having a frequency dependent on the speed of rotation of the rotary shaft 7.

An internal jacket 9, cylindrical in shape overall, is mounted in the main casing 2, being slightly spaced apart radially from the external wall of this main casing 2 in order to define a substantially cylindrical intermediate space 10 in which a cooling liquid of this jacket 9 circulates.

This main casing, which also has a cylindrical shape overall, is provided with a channel 11 for admitting cooling liquid into the space 10 and a channel 12 for discharging cooling liquid out of this space 10.

This jacket 9 surrounds several field coils 13, which are carried by a rotor 14 rigidly fixed to the rotary shaft 7. Each field coil 13 is oriented so as to generate a radial magnetic field while having an oblong shape overall extending parallel to the shaft 7. The various field coils 13 are interconnected with each other so as to form a dipole.

In a known fashion, the jacket 9 and the body of the rotor 14 are made from ferromagnetic material. Here the casing is a castable piece based on aluminium and sealing joints intervene between the casing and jacket 9; the cover 3 and the piece 4 are perforated.

The field coils 13 are supplied electrically by the rotor secondary windings 5 of the generator via a bridge rectifier carried by the rotary shaft 7. This bridge rectifier can be the one that is marked 15 in FIG. 2 and that comprises six diodes 15A-15F, in order to rectify the three-phase alternating current issuing from the secondary windings 5A-5D into direct current. This bridge rectifier can also be of another type, being for example formed from transistors of the MOSFET type.

In the example in FIG. 2, the bridge rectifier 15 is a circuit with three arms each carrying two diodes in series, each phase of the secondary windings is connected to a corresponding arm, between the two diodes. Each arm has an end connected to a first terminal of the load, formed by the field coils 13, and a second end connected to a second terminal of this load 13.

Thus the first phase SA is connected to the two diodes 15A and 15D, which are connected respectively to the first and second terminal of the load 13. The second phase 5B is connected to the diodes 15B and 15E, which are themselves connected respectively to the first and second terminal of the load 13. The third phase is connected to the diodes 15C and 15F, which are themselves connected respectively to the first and second terminal of the load 13.

In operation, each arm of the rectifier delivers in the load 13 a current having the appearance of the sinusoidal positive parts of the voltage signal of the phase corresponding to this arm, this current being zero when the voltage in question is negative.

The three phases being offset with respect to one another by a third of a period, they deliver in the load a substantially constant current, having an appearance corresponding to the sum of the positive parts of the sinusoids of the three phases.

As can be seen in FIG. 1, the rotor 14 carrying the field coils 13 has the general shape of a hollow cylinder connected to the rotary shaft 7 by radial arms 16. This rotor 14 thus defines an annular internal space situated around the shaft 7, this internal space being ventilated by an axial fan 17 situated substantially in line with the join between the cover 3 and the casing 2. A radial fan 18 is situated at the opposite end of the casing 2 in order to discharge the air introduced by the axial fan 17.

Bringing the retarder into service consists of injecting into the primary coils 8 an excitation current coming from the electrical system of the vehicle and in particular the battery, so that the current generator delivers an induced current on its secondary windings 5. This current then supplies the field coils 13 in order to produce a resisting torque retarding the vehicle.

The excitation current is injected into the primary coils 8 by means of a control box 19, shown in FIG. 2, which is interposed between an electrical supply source of the vehicle, and the primary coils 8. In the example in FIG. 2, the control box 19 and the primary coils 8 are connected in series between an earth M of the vehicle and a supply Batt of the vehicle battery. As can be seen in this figure a diode D is connected at the terminals of the primary coils 5 so as to prevent the circulation of a reverse current in the primary coils.

This control box 19 comprises an input able to receive a control signal representing a level of retarding torque demanded of the retarder.

This input can be connected to a lever or the like that is actuated directly by a driver of the vehicle. This lever may be able to move gradually between two extreme positions, namely a maximum position corresponding to a demand for maximum resisting torque and a minimum position in which the retarder is not acted on.

When the driver places this lever in an intermediate position, the retarder is controlled by the box 19 in order to exert on the rotary shaft 7 a resisting torque proportional to the position of the lever, with respect to the maximum retarding torque available. In other words, the input of the control box 19 receives a control signal that corresponds to a value lying between zero and one hundred percent.

This input can also be connected to a braking control box that autonomously determines a control signal for the retarder. This braking control box is then connected to one or more braking actuators that the vehicle has. In this case, the driver does not act directly on the retarder but it is the braking control box that, from the various parameters, controls the retarder and the traditional brakes of the vehicle.

The control box 19, visible in FIG. 4, is a electronic box comprising for example a logic circuit of the ASIC type functioning at 5V, and/or a power control circuit capable of managing currents of high intensity. This box therefore comprises electronics or a power module PU.

On reception of a control signal corresponding to a non-zero value, the control box 19 determines a set intensity value Ci of the excitation current to be injected into the primary coils 8, and applies, via its module PU, to the primary coils 8, a voltage U for injecting a current corresponding to this set intensity Ci.

The current injected into the primary coils 8 has a theoretical intensity It that increases until it reaches the set value Ci. The level of the theoretical current It is determined in the control box from a transfer function Ft that depends in particular on the inductance and electrical resistance of the primary coils 8 so as to represent the electrical behaviour of the primary coils in transient mode.

As visible in FIG. 2, the retarder 1 also comprises a sensor 21 that measures the intensity le of the current actually flowing in the primary coils 8 and that delivers a signal representing this intensity. This sensor 21 is connected to the control box 19, which is programmed to compare the actual intensity Ie measured by the sensor 21 with the theoretical current It.

A difference between the theoretical current It and the actual intensity le greater than a predetermined value signifies a malfunctioning of an electrical component of the rectifier 15, such as in particular the destruction of a diode.

This is because, when a diode is defective, it becomes permanently either electrically conductive or non-conductive. This causes an electrical imbalance in the three phases 5A, 5B and 5C of the secondary windings 5, which generates a so-called mutual current in the primary coils 8.

This phenomenon is visible in the graph in FIG. 3, which shows the theoretical current It and the actual intensity le in the case where one of the diodes of the rectifier 15 is defective.

As can be seen in this figure, the mutual currents resulting from this defective diode interfere with the current passing through the primary coils. Thus, instead of having a substantially constant appearance, the current Ie actually flowing in the primary coils 8 has a sinusoidal appearance of high amplitude. This sinusoid has a frequency linked to the speed of the rotary shaft 7.

In normal operation of the retarder, the actual current curve le is substantially merged with the theoretical current curve It.

Thus the detection from the control box 19 of a difference between the actual current Ie and the theoretical current It greater than a predetermined value makes it possible to detect a fault in the rectifier 15 mounted on the rotary shaft 7. This detection is made without contact, that is to say without having to transmit data issuing from sensors mounted on the rotary shaft 7 to a fixed part of the retarder.

The predetermined difference value is advantageously twenty percent of the value of the theoretical current It since, as can be seen in FIG. 3, the amplitude of the neutral currents is relatively high, which facilitates detection thereof. This predetermined value can also be a fixed value.

Basing the fault detection on a comparison of the actual current le with the theoretical current It makes it possible in particular to effect a pertinent detection including when the retarder is in transient mode.

It is also possible to provide a detection based on a comparison of the actual current le with the set current value, provided that the retarder is in continuous operation.

In the case in FIG. 3, the intensity le comes from a current sensor connected in a series with the primary coils 8. However, this current sensor can also be in the form of one or more measuring field turns wound with the primary coils 8. In this case, the voltage appearing at the terminals of these measuring field turns has the same trend as the current flowing in these field turns.

Because of the sinusoidal oscillations caused by the mutual currents resulting from a defective diode, the comparison of the theoretical current It with the actual intensity le can consist of determining the maximum or minimum value taken by the actual intensity le for a predetermined period corresponding to several rotation periods of the shaft 7 and comparing this maximum or minimum with the set value Ci.

As shown schematically in FIG. 4, the current It injected into the primary coils 8 is slaved to the sensor 21, so as best to correspond to the set intensity value Ci, this slaving being implemented at the control box 19.

The control box comprises, in the aforementioned manner, power electronics PU controlled by a corrector CR so as to inject the excitation current Ii into the primary coils 8, which gives rise to the current induced in the secondary windings 5. The actual intensity le is subtracted at 50 from the set intensity value Ci in order to constitute an input signal for the corrector CR controlling the power electronics PU.

When the corrector receives a negative signal as an input, it controls the power electronics PU in order to reduce the current injected and, when it receives a positive signal as an input, it controls the power electronics in order to increase the current injected.

As shown schematically in FIG. 4, the actual current le flowing in the primary coils 8 corresponds to the current Ii injected by the control box 19 from which the mutual current Im resulting from a malfunctioning of the rectifier 15 is subtracted at 40.

The theoretical current It is determined in the control box 15 from the set value Ci, on the basis of the transfer function Ft that in particular represents the intensity response of the primary coils 8 to the application of a voltage U.

In order to ensure reliable detection of a fault in a diode, the slaving of the injected current does not compensate for the disturbances due to the mutual currents in the case of a defective diode.

This can be obtained by sizing the primary coils so that they have a time constant T1 greater than N times the time constant T2 of the secondary windings 5, N designating a natural integer. Advantageously N is chosen greater than or equal to 3 so that this time constant T1 is greater than three times the time constant T2 so as to ensure optimal independence of the detection.

This can also be obtained by the choice of a sufficiently slow slaving vis-à-vis the frequency of the oscillations due to the mutual currents. Such a slaving is thus insensitive to the disturbances introduced by a malfunctioning of an electrical component carried by the rotary shaft. In this case, the slaving of the injected current is chosen so as to have a cutoff frequency Fc satisfying the relationship Fc<1/(2.N.pi.T2), in which Fc is expressed in hertz and T2 in seconds, pi representing the number having a value close to 3.14. In a similar manner, N is a natural integer that is advantageously chosen as equal to three.

The invention thus makes it possible to detect, without contact, a fault in an electrical component of the rotor, this component being able to be a diode or a transistor of the rectifier 15, but this component also being able to be a secondary winding 15A, 15B or 15C.

The example described above concerns a retarder in which the generator comprises three-phase secondary windings, but the invention also applies to a retarder comprising secondary windings having a different number of phases, equal at a minimum to two.

1. Method of detecting a fault in an electrical component carried by a rotary shaft (7) of an electromagnetic retarder (1), said retarder comprising primary stator coils (8), a control box (19) for injecting into said primary coils (8) a current having an intensity corresponding to a theoretical intensity (It) dependent on a set intensity value (Ci), a sensor (21) delivering a signal representing an actual intensity value (Ie) of the current flowing in said primary coils (8), a rotary shaft (7) carrying secondary windings (5) defining several phases and field coils (13) as well as a current rectifier interposed between the secondary windings (5) and the field coils (13), said method comprising the steps of comparing, in the control box, the theoretical intensity (It) and the actual intensity (Ie) so as to identify a fault in the event of a difference between the theoretical intensity (It) and the actual intensity (Ie) greater than a threshold value.

2. Method according to claim 1, consisting of determining a difference between the theoretical intensity (It) and a minimum or maximum value taken by the actual intensity (Ie) of the current actually passing through the primary coils (8) during a predetermined interval of time.

3. Method according to claim 1, in which the theoretical intensity (It) is determined in the control box (19) from the set intensity value (Ci) and data representing a transfer function (Ft) of the retarder.

4. Method according to claim 3, consisting of taking into account the set intensity value Ci as the value representing the theoretical intensity It.

5. Method according to claim 1, further comprising the step of slaving, from the control box (19), the current injected into the primary coils (8) to the signal delivered by the current sensor (21), and providing primary coils (8) having a time constant (T1) three times greater than the time constant (T2) of the secondary windings (5).

6. Method according to claim 1, further comprising the step of slaving, from the control box (19), the current injected into the primary coils (8) to the signal delivered by the sensor (21), with a slaving having a reaction time sufficiently long to be insensitive to a fault in an electrical component carried by the rotary shaft (7).

7. Method according to claim 6, consisting of providing a slaving having a cutoff frequency Fc satisfying the relationship Fc<1/(3.2.pi.T2), in which Fe is expressed in hertz and in which T2 is the time constant of the secondary windings expressed in seconds.

8. Method according to claim 1, further comprising the step of using measuring field turns as the actual current sensor (Ie).

9. Electromagnetic retarder comprising primary stator coils (8), a control box (19) for injecting into said primary coils (8) a current having an intensity corresponding to a theoretical intensity (It) dependent on a set intensity value (Ci), a sensor (21) delivering a signal representing an actual intensity value of the current flowing in said primary coils (8), a rotary shaft (7) carrying secondary windings (5) defining several phases and field coils (13) as well as a current rectifier interposed between the secondary windings (5) and the field coils (13), and means of comparing the theoretical intensity (It) with the actual intensity (Ie) in order to identify an operating fault in an electrical component carried by the rotary shaft (7) in the event of a difference between the theoretical intensity (It) and the actual intensity (Ie) greater than a threshold value.

10. Electromagnetic retarder according to claim 9, comprising means of slaving the current injected into the primary coils (8) to the signal delivered by the sensor (21), and primary coils (8) having a time constant (T1) greater than three times the time constant (T2) of the secondary windings.

11. Electromagnetic retarder according to claim 10, comprising means of slaving the current injected into the primary coils (8) to the signal delivered by the sensor (21), and in which this slaving has a cutoff frequency Fc satisfying the relationship Fc<1/(3.2.pi.T2), in which Fc is expressed in hertz and in which T2 is the time constant of the secondary windings expressed in seconds.

12. Retarder according to claim 9, in which the sensor (21) comprises one or more measuring field turns wound with the primary coils.
